(19) United States
(12) Patent Application Publication
(10) Pub. No.: US 2012/0003489 A1
(43) Pub. Date: Jan. 5, 2012

(54) DECORATION FILM, DECORATION DEVICE AND METHOD FOR FABRICATING DECORATION FILM

(75) Inventor: Kuo-Liang Ying, Taoyuan County (TW)

(73) Assignee: SiPix Chemical Inc., Taoyuan County (TW)

(21) Appl. No.: 12/828,312

(22) Filed: Jul. 1, 2010

(51) Int. Cl. B32B 15/04; C23C 14/34

(52) U.S. Cl. 428/469; 428/457; 204/192.15

(57) ABSTRACT

A decoration film, a decoration device, and a method for fabricating the decoration film are provided. The decoration film includes a substrate, an adhesion layer disposed on the substrate, and a metal layer with low conductivity disposed between the substrate and the adhesion layer, wherein an electromagnetic wave passes through the metal layer with low conductivity without being completely shielded.

### BACKGROUND OF THE INVENTION

1. Field of the Invention

The present invention generally relates to a decoration film, a decoration device, and a method for fabricating a decoration film, in particular, to a decoration film having a layer with metallic gloss, a decoration device, and a method for fabricating a decoration film.

2. Description of Related Art

Conventionally, the illustrations or decorations formed on the surface of the plastic housing are mainly fabricated by spraying process or printing process to present certain effect on sense of sight. Nevertheless, the spraying process is unfavorable in mass production for the disadvantages of time consumption, process complexity, low uniformity in thickness, and the like. To solve the abovementioned problem, specific decoration processes using a decoration film which has predetermined decoration layers formed on a substrate are provided. The decoration processes include an in-mold decoration (IMD) technique, a heat transfer printing process, a sublimation heat transfer process, a hot stamping process, an ink jet printing process, a water transfer printing process, and the like.

For example, the process of the IMD technique includes placing the decoration film into a mold of the injection machine, injecting a melted resin at a side of the decoration film in the mold so that the melted resin and the decoration layers of the decoration film are combined to form a decoration device, and thereafter ejecting the decoration device from the mold. Accordingly, the in-mold decoration process is completed.

With the variety of the requirement on the appearance of the decoration device, the predetermined decoration layers must have various properties such as specific sense of touch and specific sense of sight. For example, certain decoration device is required to have metallic gloss so that a metal layer having good conductivity is formed in the decoration film by electroplating process, vacuum evaporation process, sputtering process, electron beam evaporation process, or the like to be served as the decoration layer. However, the metal layer generally has good conductivity so as to cause a metallic shield effect in the decoration device. Accordingly, an electronic product, such as a mobile phone, personal digital assistant, notebook, or the like, using the decoration device as a housing may have an undesirable quality on signal communication.

### SUMMARY OF THE INVENTION

Accordingly, the invention is directed to a decoration film conducive to provide metallic gloss without causing a metallic shield effect.

The invention is directed to a decoration device with a decoration layer having metallic gloss without causing a metallic shield effect.

The invention is further directed to a method for fabricating a decoration film having metallic gloss without causing a metallic shield effect.

The invention provides a decoration film including a substrate, an adhesion layer disposed on the substrate, and a metal layer with low conductivity disposed between the substrate and the adhesion layer, wherein an electromagnetic wave passes through the metal layer with low conductivity without being completely shielded.

According to an embodiment of the invention, the decoration film further includes a releasing layer disposed between the metal layer with low conductivity and the substrate, wherein the releasing layer contacts the substrate.

According to an embodiment of the invention, a material of the metal layer with low conductivity includes a material with metallic gloss and a dopant material. Specifically, the material with metallic gloss is selected from Sn, Cr, Ti, Ni, Zn, Mo Al, Au, Ag, Cu, or a combination thereof. The dopant material is selected from In, Sn, Au, Ag, Cu, Co, W, Al, Cr, Ni, Zr, Zn, Pt, Pd, Mo, TiO2, TiOx, ZrO, SiO2, or a combination thereof. In an embodiment, a color or a gloss of the metal layer with low conductivity is changed along with a material of the dopant material.

According to an embodiment of the invention, the decoration film further comprises an ink layer disposed between the substrate and the adhesion layer. In an embodiment, the ink layer is located between the metal layer with low conductivity and the substrate. Alternatively, the ink layer is located between the metal layer with low conductivity and the adhesion layer.

According to an embodiment of the invention, the decoration film further includes an oxide layer disposed on at least a side of the metal layer with low conductivity. A material of the oxide layer includes titanium oxide (TiO2), zinc oxide (ZnO), aluminum oxide (Al2O3), indium tin oxide (ITO), indium oxide (In₂O₃), tin oxide (SnO₂), magnesium oxide (MgO), copper oxide (CuO), zirconium dioxide (ZrO), silicon dioxide (SiO₂), or a combination thereof.

The invention also provides a decoration device including a housing, a metal layer with low conductivity, an adhesion layer, and an outer layer. The metal layer with low conductivity is disposed on a surface of the housing, wherein an electromagnetic wave passes through the metal layer with low conductivity without being completely shielded. The adhesion layer is disposed between the housing and the metal layer with low conductivity. The outer layer is disposed on the metal layer with low conductivity away from the adhesion layer.

According to an embodiment of the invention, a material of the metal layer with low conductivity includes a material with metallic gloss and a dopant material. In an embodiment, the material with metallic gloss can be selected from Sn, Cr, Ti, Ni, Zn, Mo Al, Au, Ag, Cu, or a combination thereof. In addition, the dopant material can be selected from In, Sn, Au, Ag, Cu, Co, W, Al, Cr, Ni, Zr, Zn, Pt, Pd, Mo, TiO2, TiOx, ZrO, SiO2, or a combination thereof. In an embodiment, a color or a gloss of the metal layer with low conductivity is changed along with a material of the dopant material.

According to an embodiment of the invention, the decoration device further includes an ink layer disposed between the outer layer and the adhesion layer. In one embodiment, the ink layer is located between the metal layer with low conductivity and the outer layer. Alternatively, the ink layer is located between the metal layer with low conductivity and the adhesion layer.

According to an embodiment of the invention, the outer layer is a substrate, a releasing layer, or a protection layer.

According to an embodiment of the invention, the decoration film further includes an oxide layer disposed on at least a side of the metal layer with low conductivity. A material of the oxide layer includes titanium oxide (TiO2), zinc oxide (ZnO), aluminum oxide (Al2O3), indium tin oxide (ITO), indium oxide (In₂O₃), tin oxide (SnO₂), magnesium oxide (MgO), copper oxide (CuO), zirconium dioxide (ZrO), silicon dioxide (SiO₂), or a combination thereof.

The invention further provides a method for fabricating the aforesaid decoration film, wherein the metal layer with low conductivity is formed by performing an evaporation process or a sputtering process.

According to an embodiment of the invention, a target material of the evaporation process or the sputtering process includes a material with metallic gloss and a dopant material. In one embodiment, the material with metallic gloss can be selected from Sn, Cr, Ti, Ni, Zn, Mo Al, Au, Ag, Cu, or a combination thereof. The dopant material can be selected from In, Sn, Au, Ag, Cu, Co, W, Al, Cr, Ni, Zr, Zn, Pt, Pd, Mo, TiO₂, TiOₓ, ZrO, SiO₂, or a combination thereof. In an embodiment, a color or a gloss of the metal layer with low conductivity is changed along with a material of the dopant material.

According to an embodiment of the invention, the method further includes forming an oxide layer disposed on at least a side of the metal layer with low conductivity. A material of the oxide layer includes titanium oxide (TiO2), zinc oxide (ZnO), aluminum oxide (Al2O3), indium tin oxide (ITO), indium oxide (In₂O₃), tin oxide (SnO₂), magnesium oxide (MgO), copper oxide (CuO), zirconium dioxide (ZrO), silicon dioxide (SiO₂), or a combination thereof.

In view of the above, a metal layer with low conductivity fabricated by an evaporation process or a sputtering process is formed in the decoration film. The metal layer with low conductivity is conducive to provide metallic gloss of a decoration device while less or no metallic shield effect is caused by the metal layer with low conductivity. Therefore, the requirement of metallic gloss on the decoration device is accomplished and the signal communication quality of an electronic product having the decoration device is favorable.

In order to make the aforementioned and other features and advantages of the invention more comprehensible, embodiments accompanying figures are described in detail below.

Herein, the same or similar reference numbers used in the drawings and the descriptions are referred as the same or similar elements. For clearly describing the concept of the invention, the shapes and the thickness of the elements in the embodiments accompanying with the drawings may not definitely comply with the real circumstance. In addition, the following descriptions are directed to the elements or the combinations thereof, but the elements are not particularly restricted in the contents or the descriptions. Any form or shape known by one skilled in the art is applicable in the invention. Moreover, the description that a material layer disposed on a substrate or disposed on another material layer means that the material layer is directly located on the substrate or the another material layer, and may also mean that some interlayer is interrupted between the material layer and the substrate or between the material layer and the another material layer.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a decoration film according to a first embodiment of the invention.

FIG. 2 schematically illustrates a decoration device fabricating by using the decoration film of FIG. 1 according to the first embodiment of the invention.

FIG. 3 schematically illustrates a decoration film according to a second embodiment of the invention.

FIG. 4 schematically illustrates a decoration device fabricating by using the decoration film of FIG. 3 according to the second embodiment of the invention.

FIG. 5 schematically illustrates a decoration film according to a third embodiment of the invention.

FIG. 6 schematically illustrates a decoration device fabricating by using the decoration film of FIG. 5 according to the third embodiment of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

For achieving a particular metallic gloss without causing metallic shield effect in a decoration device, the following descriptions exemplified depict a decoration film having a metal layer with low conductivity and the application thereof. Several decoration processes such as an in-mold decoration (IMD) technique, a heat transfer printing process, a sublimation heat transfer process, a hot stamping process, an ink-jet printing process, a water transfer printing process, and the like are provided for forming a decoration device, wherein the IMD technique substantially includes an in-mold labelling (IML) process, an in-mold film (IMF) process, an in-mold roller (IMR) process, or the like. It is noted that the decoration film described hereinafter can be applied in any of the aforesaid decoration processes, but the invention is not limited thereto.

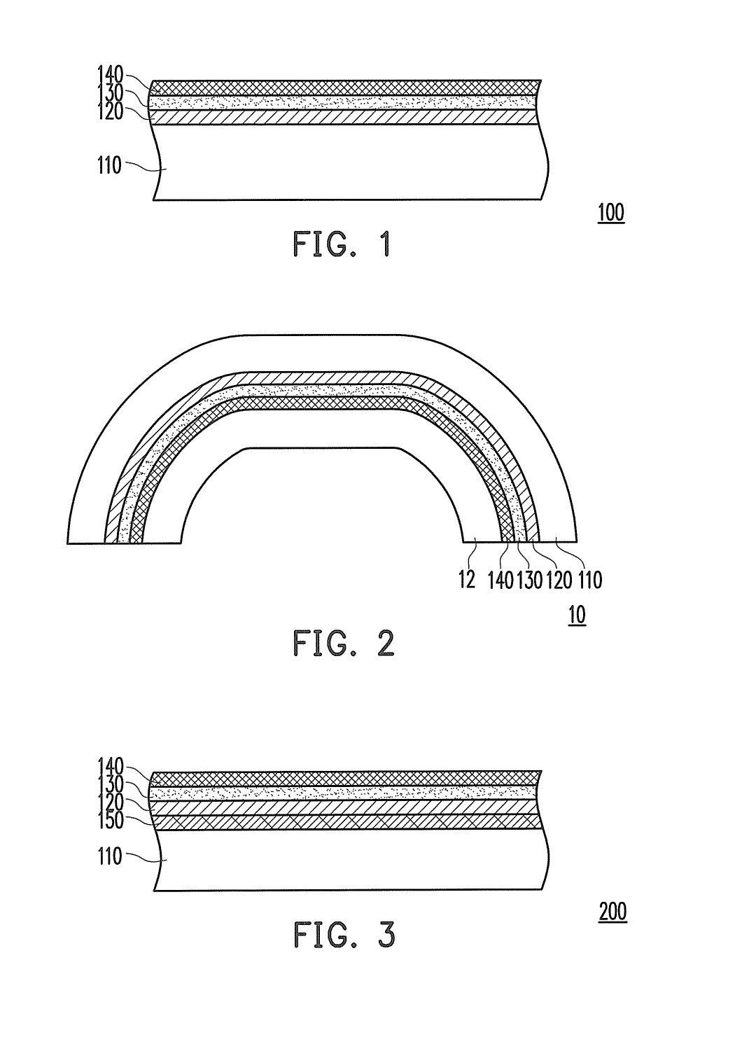

FIG. 1 schematically illustrates a decoration film according to a first embodiment of the invention. Referring to FIG. 1, a decoration film 100 includes a substrate 110, an ink layer 120, a metal layer with low conductivity 130, and an adhesion layer 140. The ink layer 120, the metal layer with low conductivity 130, and the adhesion layer 140 are sequentially disposed on the substrate 110. Specifically, the ink layer 120 is formed between the metal layer with low conductivity 130 and the substrate 110 in the present embodiment. Alternately, in another embodiment, the metal layer with low conductivity 130 can be selectively formed between the ink layer 120 and the substrate 110. Namely, the disposition locations of the ink layer 120 and the metal layer with low conductivity 130 are not restricted in the invention.

Specifically, the metal layer with low conductivity 130 is conducive to provide metallic gloss without causing metallic shield effect. Therefore, an electromagnetic wave can pass through the metal layer with low conductivity 130 without being completely shielded. In the present embodiment, the metal layer with low conductivity 130 can be fabricated by an evaporation process or a sputter process in which a target is used for providing a layer forming material. For achieving the property of metallic gloss without causing metallic shield effect, the material of the target is particularly selected. In addition, a thickness of the metal layer with low conductivity 130 can be modulated based on the designs such as the required metallic gloss, the material of the metal layer with low conductivity 130, and the like. For example, the material of the target can include a material with metallic gloss and a dopant material with poor electric property. Specifically, the material with metallic gloss can be selected from Sn, Cr, Ti, Ni, Zn, Mo Al, Au, Ag, Cu, or a combination thereof and the dopant material can be selected from In, Sn, Au, Ag, Cu, Co, W, Al, Cr, Ni, Zr, Zn, Pt, Pd, Mo, TiO₂, TiOₓ, ZrO, SiO₂, or a combination thereof. Accordingly, the metal layer with low conductivity 130 may include a composition of the material with metallic gloss and the dopant material with poor electric property mentioned above. In addition, a color or a gloss of the metal layer with low conductivity 130 can be changed along with a material of the dopant material so as to present specific color such as light golden yellow, dark red, etc.

It is noted that the dopant material generally has poor conductivity and thus the layer formed by the evaporation process or the sputter process using the target would have low conductivity. Accordingly, the metal layer with low conductivity 130 fabricated by the evaporation process or the sputter process using the target can have metallic gloss without causing metallic shield effect. However, the material of the target is not limited hereto, in an alternate embodiment, other materials conducive to provide metallic gloss with poor electric property can be served as the material of the target.

In an embodiment, the decoration film 100 can further include an oxide layer (not shown) disposed on at least a side of the metal layer with low conductivity 130, wherein a material of the oxide layer (not shown) includes titanium oxide (TiO2), zinc oxide (ZnO), aluminum oxide (Al2O3), indium tin oxide (ITO), indium oxide (In₂O₃), tin oxide (SnO₂), magnesium oxide (MgO), copper oxide (CuO), zirconium dioxide (ZrO), silicon dioxide (SiO₂), or a combination thereof. Specifically, the oxide layer (not shown) can be disposed between the metal layer with low conductivity 130 and the ink layer 120, or disposed between the metal layer with low conductivity 130 and the adhesion layer 140, thereby a specific color such as light golden yellow or dark red or a specific gloss such as gloomy metallic gloss or bright metallic gloss can be presented.

The ink layer 120 can be a colourful ink layer, a black ink layer, or a white ink layer so as to form an ink pattern. The ink layer 120 can be formed by any suitable printing process such as a gravure printing, process, a screen printing process, a flexographic printing process, an offset printing, a reverse printing process, an ink jet printing process on the substrate 110 while a material of the ink layer 120 can be sublimation type transferring ink, heat-melted type transferring ink, UV-type transferring ink, and the like. In the present embodiment, the adhesion layer 140 can be formed by the material selected from polyacrylate, polymethacrylate, polystyrene, polycarbonate, polyurethane, polyester, polyamide, epoxy resin, ethylene vinylacetate copolymer (EVA) or thermoplastic elastomer or a copolymer, blend or composite thereof.

In addition, a material of the substrate 110, which is a flexible substrate, can be polyethylene terephthalate (PET), polyethylene naphthalate (PEN), polyethylene glycol-co-cyclohexane-1,4 dimethanol terephthalate (PETG), thermalplastic polyurethane (TPU), polyurethane (PU), polypropylene (PP), polycarbonate (PC), amorphous polyethylene terephthalate (A-PET), polyvinyl chloride (PVC), Polystyrene (PS), triacetyl cellulose (TAC), polymethylmethacrylate (PMMA), methylmethacrylate-styrene (MMA-st, MS) copolymer, cycloolefin copolymer (COC) and a combination thereof, but the invention is not restricted herein. The adhesion layer 140 may be formed from a material such as polyacrylate, polymethacrylate, polystyrene, polycarbonate, polyurethane, polyester, polyamide, epoxy resin, ethylene vinylacetate copolymers (EVA), thermoplastic elastomers or the like, or copolymers, blends or composites thereof. Hot melt or heat activated adhesions such as polyurethane and polyamide are particularly preferred. In addition to the materials indicated above, a composition suitable for an adhesion layer is disclosed in US 2006/0019088, the content of which is incorporated herein by reference in its entirety. Briefly, the adhesion layer composition may comprise an adhesion binder and a polymeric particulate material.

The decoration film 100 can be applied in an IML process, wherein the decoration film 100 is adhered on a plastic housing through the adhesion layer 140 therein. Therefore, a decoration device as shown in FIG. 2 is provided as an embodiment. Referring to FIG. 2, a decoration device 10 includes a housing 12, the adhesion layer 140, the metal layer with low conductivity 130, the ink layer 120, and the substrate 110.

Specifically, the housing 12 can be fabricated by a molding process such as an injection molding process, a thermoforming process, a compression molding process, a blow molding process, a thermal printing process, an injection molding process, a compression process, or a combination thereof. A material of the housing 12 includes polycarbonate (PC), polypropylene (PP), polymethylmethacrylate (PMMA), methylmethacrylate-styrene (MMA-st, MS) copolymer, MS, acrylonitrile butadiene styrene (ABS), polystyrene (PS), polyethylene terephthalate (PET), polyoxymethylene (POM) or a combination thereof.

It is noted that the substrate 110 remains on the decoration device 10 after the IML process. Therefore, the substrate 110 is the outer layer of the decoration device 10 and the adhesion layer 140, the metal layer with low conductivity 130, and the ink layer 120 are sandwiched between the substrate 110 and the housing 12. In addition, the adhesion layer 140 directly contacts the housing 140 for providing an adhesion effect. Under this configuration, the substrate 110 served as the outermost layer of the decoration device 10 is conducive to provide protection effect and thus no additional protection layer is required in the present embodiment. However, the invention is not restricted herein and the protection layer can be selectively formed in other decoration device.

The ink layer 120 covers the metal layer with low conductivity 130 in the present embodiment while the ink layer 120 may allow an ambient light to transmit therethrough so that the decoration device 10 can provide the effect of metallic gloss on the sense of sight in the decoration device 10. In an alternative embodiment, if the disposition locations of the metal layer with low conductivity 130 and the ink layer 120 are interchanged with each other and the metallic layer with low conductivity 130 would cover the ink layer 120. For allowing the ink layer 120 to provide illustrations, the metal layer with low conductivity 130 may be required to allow light to transmit therethrough. In other words, the ink layer 120 and the metal layer with low conductivity 130 both can provide individual effect on the sense of sight without obstructing each other.

For example, a specific color and a specific gloss, particularly the metallic gloss, can be shown by the dispositions of the ink layer 120 and the metal layer with low conductivity 130. Therefore, the appearance of the decoration device 10 can comply with the requirement of various products. In addition, the metal layer with low conductivity 130 has low conductivity so that an electromagnetic wave is capable of passing through the metal layer with low conductivity 130. Accordingly, an electronic product using the decoration device 10 as a housing can have desirable signal communication quality.

In the embodiment illustrated in FIG. 1 and FIG. 2, the ink layer 120 is completely formed on the whole surface of the substrate 110. Nevertheless, the ink layer 120 can be formed partially on the surface of the substrate 110 in another embodiment. That is to say, the ink layer 120 can be selectively formed on a portion of the substrate 110 so as to constitute a required pattern with the specific color. In an embodiment, the partially formed ink layer 120 can be achieved by disposing a patterned shielding layer (not shown) to cover the blank region which is not supposed to be disposed with ink layer 120 on the substrate 110. Under this method, the patterned shield layer (not shown) can be selectively removed after forming the ink layer 120 so that the partially formed ink layer 120 is accomplished. In addition, the ink layer 120 can include one or more color ink layer(s) and the invention is not restricted herein. Certainly, the decoration film 100 may further have other layers with specific properties such as rough surface, easy-clean property, aromatic property, haze effect on the sense of sight, etc. and the layers with specific properties can be selectively formed between the adhesion layer 140 and the metallic layer with low conductivity 130. In other embodiments, the ink layer 120 can be optionally omitted so that a decoration device can have only the substrate 110, the metal layer with low conductivity 130, and the adhesion layer 140.

FIG. 3 schematically illustrates a decoration film according to a second embodiment of the invention. Referring to FIG. 3, a decoration film 200 includes a substrate 110, a releasing layer 150, an ink layer 120, a metal layer with low conductivity 130, and an adhesion layer 140. It is noted that the decoration film 200 is similar to the decoration film 100 mentioned above in addition to the releasing layer 150. Therefore, the materials, the dispositions, the characteristics of the substrate 110, the ink layer 120, the metal layer with low conductivity 130, and the adhesion layer 140 can be referred to the description in the first embodiment, and are not repeated herein.

In the present embodiment, the releasing layer 150 is disposed between the substrate 110 and the ink layer 120 and directly contacts the substrate 110. The releasing layer 150 is usually a thin film with low surface tension which can be made of a wax, a paraffin, or silicone, or an impermeable thin film with high smoothness which can be made of an irradiation curable multi-functional acrylic, silicone acrylate, epoxy, vinyl, allyl vinyl compound, unsaturated polyester or a mixture thereof. A material of the releasing layer 150 can be selected from a polycondensate, a copolymer, a blend, or a mixture consisting of epoxy, polyurethane, polyimide, polyamide, hexa methoxymethyl melamine-formaldehyde, urea-formaldehyde, phenol-formaldehyde, and a combination thereof. Accordingly, the releasing layer 150 can provide a removable effect.

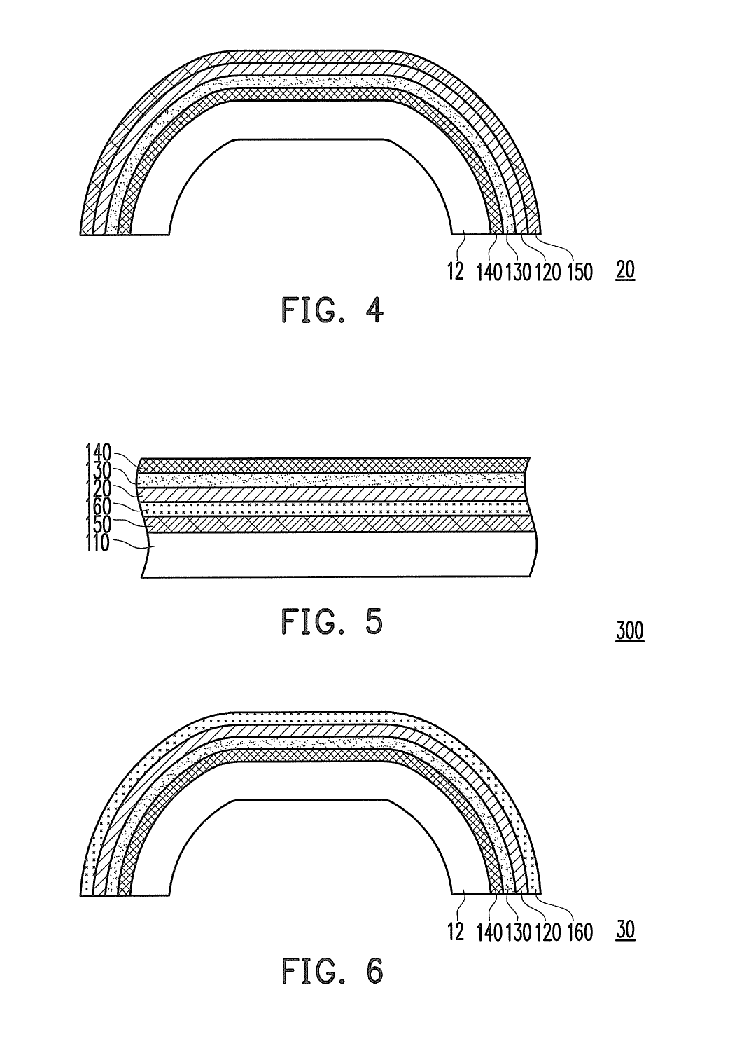

Specifically, FIG. 4 schematically illustrates a decoration device fabricating by using the decoration film of FIG. 3 according to a second embodiment of the invention. Referring to FIG. 3 and FIG. 4 simultaneously, the decoration film 200 can be used in a decoration process such as an IMF process, an IMR process, a heat transfer printing process, a sublimation heat transfer process, a hot stamping process, an ink jet printing process, a water transfer printing process, or the like. During the decoration process, the decoration film 200 is combined with a housing 12, wherein the adhesion layer 140 is adhered on a surface of the housing 12. After the decoration process, the substrate 110 is separated from the releasing layer 150 so that a decoration device 20 is formed. It is noted that the substrate 110 is not remained on the decoration device 20 so that the releasing layer 150 is the outer layer of the decoration device 20.

In the present embodiment, the ink layer 120 and the metal layer with low conductivity 130 can provide required effects on the sense of sight as described in the first embodiment. Therefore, the decoration device 20 can have a required illustration and metallic gloss. In addition, the metal layer with low conductivity 130 allows an electromagnetic wave to pass therethrough so that the decoration device 20 can be used as a housing of an electronic product without affecting the signal communication quality of the electronic product. Therefore, the decoration device 20 can have wider applications.

It is noted that the ink layer 120 is located between the metal layer with low conductivity 130 and the substrate 110 in the present embodiment. However, the ink layer 120 can be selectively disposed between the metal layer with low conductivity 130 and the adhesion layer 140 and the invention is not limited thereto. In addition, the ink layer 120 can be a single layer, a multiple layer, or a patterned layer so as to show a single color, a plurality of colors, or a required pattern respectively.

Certainly, the decoration film 200 may further have other layers with specific properties such as rough surface, easy-clean property, aromatic property, haze effect on the sense of sight, etc. and the layers with specific properties can be selectively formed between the releasing layer 150 and the metallic layer with low conductivity 130.

For example, an oxide layer (not shown) disposed on at least a side of the metal layer with low conductivity 130, which is made of titanium oxide (TiO2), zinc oxide (ZnO), aluminum oxide (Al2O3), indium tin oxide (ITO), indium oxide (In₂O₃), tin oxide (SnO₂), magnesium oxide (MgO), copper oxide (CuO), zirconium dioxide (ZrO), silicon dioxide (SiO₂), or a combination thereof can be conducive to present a specific color such as light golden yellow or dark red or a specific gloss such as gloomy metallic gloss.

In addition, the outer layer, i.e. the releasing layer 150 in the present embodiment can optionally have a rough surface away from the adhesion layer 140 to provide a rough touching sense or a haze effect on the sense of sight. In an embodiment, the releasing layer 150 can have a rough surface by disposing a haze layer (not shown) between the substrate 110 and the releasing layer 150, wherein a plurality of particles (not shown) is distributed in the haze layer (not shown) and the surface of the releasing layer 150 can become rough due to the particles. In an embodiment, the particles can have a diameter from 0.1 μm to 30 μm, preferably 1 μm to 15 μm and a material of the particles can be silicon dioxide, calcium carbonate, calcium sulphate, barium sulphate, aluminium oxide, titanium oxide, metal powders, inorganic dye, or organic dye. In addition, the particles can be a plurality of hollow balls, non-film-forming latexes, or dispersions.

FIG. 5 schematically illustrates a decoration film according to a third embodiment of the invention and FIG. 6 schematically illustrates a decoration device fabricating by using the decoration film of FIG. 5 according to a second embodiment of the invention. Referring to FIG. 5, a decoration film 300 includes all elements of the decoration film 200 and a protection layer 160. In the present embodiment, the protection layer 160 is disposed between the releasing layer 150 and the ink layer 120. Therefore, a decoration device 30 as shown in FIG. 6 can be formed by a decoration process using the decoration film 300, wherein the substrate 110 and the releasing layer 150 are separated from the protection layer 160 after the decoration process.

In the present embodiment, the protection layer 160 is the outer layer of the decoration device 30 so as to provide a protection effect. The protection layer 160 can be an irradiation curable material layer, i.e. a thermal curing resin, an UV irradiated reaction resin or the like. Specifically, suitable raw materials for the protection layer 160 may include, but are not limited to, radiation curable multifunctional acrylates including epoxy acrylates, polyurethane acrylates, polyester acrylates, silicone acrylates, glycidyl acrylates, epoxides, vinyl esters, diallyl phthalate, vinyl ethers and blends thereof. The protection layer 160 may comprise a condensation polymer or copolymer, such as epoxy, polyurethane, polyamide, polyimide, melamine formaldehyde, urea formaldehyde or phenol formaldehyde. The protection layer 160 may include a sol-gel silicate or titanium ester.

The protection layer 160 may be partially or fully cured. If partially cured, a post curing step will be employed after the molding and/or transferring step to enhance the durability, particularly hardness, scratch and oil resistance. To improve the release properties, the raw material, particularly the low molecular weight components of the protection layer 160 is preferably not permeable into the release layer 150. After the protection layer 160 is coated and cured or partially cured, it should be marginally compatible or incompatible with the release layer 150. Binders and additives such as thickeners, surfactants, dispersants, UV stabilizers or antioxidants may be used to control the rheology, wettability, coating properties, weatherability and aging properties. Fillers such as silica, Al₂O₃, TiO₂, CaCO₃, microcrystalline wax or polyethylene, Teflon or other lubricating particles may also be added to improve, for example, scratch resistance and hardness of the protection layer 160. The protection layer 160, if present, is preferably transparent in a window area.

In addition to the materials described above, other suitable compositions for the optional protection layer 160 are disclosed in US 2005/0181204, US 2005/0171292, and US 2006/0093813, the contents of all of which are incorporated herein by reference in their entirely. For example, US 2005/0181204 discloses a protection layer composition which comprises a thermally crosslinkable and photochemically or radically graftable polymer, a thermal crosslinker and a radiation curable multifunctional monomer or oligomer; US 2005/0171292 discloses a protection layer composition which comprises a polymer or copolymer having at least one carboxylic acid or acid anhydride functionality for thermal crosslinking and at least one UV crosslinkable functionality; and US 2006/0093813 discloses a protection layer composition which comprises an amino crosslinker, a UV curable monomer or oligomer having at least one functional group reactive with the amino crosslinker, an acid catalyst; and a photoinitiator.

Certainly, the decoration film 300 may further have other layers with specific properties such as rough surface, easy-clean property, aromatic property, haze effect on the sense of sight, etc. and the layers with specific properties can be selectively formed between the protection layer 160 and the metallic layer with low conductivity 130.

For example, an oxide layer (not shown) disposed on at least a side of the metal layer with low conductivity 130, which is made of titanium oxide (TiO2), zinc oxide (ZnO), aluminum oxide (Al2O3), indium tin oxide (ITO), indium oxide (In₂O₃), tin oxide (SnO₂), magnesium oxide (MgO), copper oxide (CuO), zirconium dioxide (ZrO), silicon dioxide (SiO₂), or a combination thereof can be conducive to present a specific color such as light golden yellow or dark red or a specific gloss such as gloomy metallic gloss.

In addition, the outer layer, i.e. the protection layer 160, in the present embodiment can optionally have a rough surface away from the adhesion layer 140 to provide a rough touching sense or a haze effect on the sense of sight. In an embodiment, the protection layer 160 can have a rough surface by conformally formed on a rough releasing layer 150. Herein, the rough releasing layer 150 can be fabricated by applying a pressing force through an element having protruding structures or by conformed to a haze layer mentioned in the aforesaid embodiment. In an alternate embodiment, the substrate 110 can be applied by a pressing force through an element having protruding structures to have rough surface so that the releasing layer 150 and the protection layer 160 formed thereon can have rough surface.

In summary, a metal layer with low conductivity is formed in the decoration film of the invention, which is conducive to provide metallic gloss of a decoration device. In addition, the metal layer with low conductivity of the invention allows an electromagnetic wave to pass therethrough so that the electronic product using the decoration device of the invention as a housing can have desirable signal communication quality. Specifically, the electronic product can effectively transmit/receive an electromagnetic wave to/from an external signal source.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A decoration film comprising:
a substrate;
an adhesion layer disposed on the substrate; and
a metal layer with low conductivity disposed between the substrate and the adhesion layer, wherein an electromagnetic wave passes through the metal layer with low conductivity without being completely shielded.

2. The decoration film according to claim 1, further comprising a releasing layer disposed between the metal layer with low conductivity and the substrate, wherein the releasing layer contacts the substrate.

3. The decoration film according to claim 1, wherein a material of the metal layer with low conductivity comprises a material with metallic gloss and a dopant material.

4. The decoration film according to claim 3, wherein the material with metallic gloss is selected from Sn, Cr, Ti, Ni, Zn, Mo Al, Au, Ag, Cu, or a combination thereof.

5. The decoration film according to claim 3, wherein the dopant material is selected from In, Sn, Au, Ag, Cu, Co, W, Al, Cr, Ni, Zr, Zn, Pt, Pd, Mo, TiO₂, TiOₓ, ZrO, SiO₂, or a combination thereof.

6. The decoration film according to claim 3, wherein a color or a gloss of the metal layer with low conductivity is changed along with a material of the dopant material.

7. The decoration film according to claim 1, further comprising an ink layer disposed between the substrate and the adhesion layer.

8. The decoration film according to claim 5, wherein the ink layer is located between the metal layer with low conductivity and the substrate.

9. The decoration film according to claim 5, wherein the ink layer is located between the metal layer with low conductivity and the adhesion layer.

10. The decoration film according to claim 1, further comprising an oxide layer disposed on at least a side of the metal layer with low conductivity.

11. The decoration film according to claim 10, wherein a material of the oxide layer comprises titanium oxide, zinc oxide, aluminum oxide, indium tin oxide, indium oxide, tin oxide, magnesium oxide, copper oxide, zirconium dioxide, silicon dioxide, or a combination thereof.

12. A decoration device comprising
a housing;
a metal layer with low conductivity disposed on a surface of the housing, wherein an electromagnetic wave passes through the metal layer with low conductivity without being completely shielded;
an adhesion layer disposed between the housing and the metal layer with low conductivity; and
a outer layer disposed on the metal layer with low conductivity away from the adhesion layer.

13. The decoration device according to claim 12, wherein a material of the metal layer with low conductivity comprises a material with metallic gloss and a dopant material.

14. The decoration device according to claim 13, wherein the material with metallic gloss is selected from Sn, Cr, Ti, Ni, Zn, Mo Al, Au, Ag, Cu, or a combination thereof.

15. The decoration device according to claim 13, wherein the dopant material is selected from In, Sn, Cr, Ti, Ni, Zn, Mo Al, Au, Ag, Cu, TiO₂, TiOₓ, ZrO, SiO₂, or a combination thereof.

16. The decoration device according to claim 12, further comprising an ink layer disposed between the outer layer and the adhesion layer.

17. The decoration device according to claim 16, wherein the ink layer is located between the metal layer with low conductivity and the outer layer.

18. The decoration device according to claim 16, wherein the ink layer is located between the metal layer with low conductivity and the adhesion layer.

19. The decoration device according to claim 12, wherein the outer layer is a substrate, a releasing layer, or a protection layer.

20. The decoration device according to claim 12, further comprising an oxide layer disposed on at least a side of the metal layer with low conductivity.

21. The decoration device according to claim 20, wherein a material of the oxide layer comprises titanium oxide, zinc oxide, aluminum oxide, indium tin oxide, indium oxide, tin oxide, magnesium oxide, copper oxide, zirconium dioxide, silicon dioxide, or a combination thereof.

22. A method for fabricating the decoration film according to claim 1, wherein the metal layer with low conductivity is formed by performing an evaporation process or a sputtering process.

23. The method according to claim 22, wherein a target material of the evaporation process or the sputtering process comprises a material with metallic gloss and a dopant material.

24. The method according to claim 23, wherein the material with metallic gloss is selected from Sn, Cr, Ti, Ni, Zn, Mo Al, Au, Ag, Cu, or a combination thereof.

25. The method according to claim 23, wherein the dopant material is selected from In, Sn, Cr, Ti, Ni, Zn, Mo Al, Au, Ag, Cu, TiO₂, TiOₓ, ZrO, SiO₂, or a combination thereof.
